(19) United States
(12) Patent Application Publication
(10) Pub. No.: US 2026/0182281 A1
(43) Pub. Date: Jun. 25, 2026

(54) ETCHING METHOD AND ETCHING APPARATUS

(71) Applicant: Tokyo Electron Limited, Tokyo (JP)

(72) Inventors: Daichi ITO, Yamanashi (JP); Jun OGAWA, Yamanashi (JP)

(21) Appl. No.: 19/411,946

(22) Filed: Dec. 8, 2025

(30) Foreign Application Priority Data
Dec. 20, 2024 (JP) 2024-225391

(51) Int. Cl. H10P 50/28; H01J 37/32

(52) U.S. Cl. CPC H10P 50/283; H01J 37/32449; H01J 2237/334

(57) ABSTRACT

An etching method is provided and includes providing a substrate including a first film over a surface of the substrate; and etching the first film. The etching includes supplying a first gas toward the substrate from outside in a radial direction of the substrate, the first gas containing a basic gas and not containing a halogen-containing gas; and after the supply of the first gas, supplying a second gas toward the substrate from the outside in the radial direction of the substrate, the second gas containing both the basic gas and the halogen-containing gas.

### CROSS-REFERENCE TO RELATED APPLICATIONS

This application is based upon and claims priority to Japanese Patent Application No. 2024-225391, filed on December 20, 2024, the entire contents of which are incorporated herein by reference.

### BACKGROUND

### 1. Field of the Invention

The present disclosure relates to an etching method and an etching apparatus.

### 2. Description of the Related Art

Japanese Laid-Open Patent Application Publication No. 2012-199306 discloses a technique of alternating formation of a silicon oxide film and etching of the silicon oxide film using a hydrogen fluoride gas and an ammonia gas, thereby embedding the silicon oxide film into a recess formed in a substrate.

### SUMMARY

An etching method according to an aspect of the present disclosure includes: providing a substrate including a first film over a surface of the substrate; and etching the first film. The etching includes: supplying a first gas toward the substrate from outside in a radial direction of the substrate, the first gas containing a basic gas and not containing a halogen-containing gas; and after the supply of the first gas, supplying a second gas toward the substrate from the outside in the radial direction of the substrate, the second gas containing both the basic gas and the halogen-containing gas.

### BRIEF DESCRIPTION OF THE DRAWINGS

FIG. 1 is a vertical cross-sectional diagram illustrating an etching apparatus according to an embodiment of the present disclosure.

FIG. 2 is a horizontal cross-sectional diagram illustrating the etching apparatus according to the embodiment.

FIG. 3 is a diagram illustrating an example of a substrate.

FIG. 4 is a timing chart illustrating an etching method according to an embodiment of the present disclosure.

FIG. 5 is a diagram (1) for describing a reaction on a surface of the substrate.

FIG. 6 is a diagram (2) for describing the reaction on the surface of the substrate.

FIG. 7 is a diagram (3) for describing the reaction on the surface of the substrate.

FIG. 8 is a diagram (4) for describing the reaction on the surface of the substrate.

FIG. 9 is a diagram illustrating distributions of etching levels in a surface of the substrate according to an Example.

FIG. 10 is a diagram illustrating distributions of etching levels in the surface of the substrate according to a Comparative Example.

### DETAILED DESCRIPTION OF THE DISCLOSURE

The present disclosure provides a technique that can adjust a distribution of an etching level in a surface of a substrate.

Hereinafter, non-limiting embodiments of the present disclosure will be described with reference to the drawings. In the drawings, the same or corresponding members or components are denoted by the same or corresponding reference signs, and duplicate description thereof will be omitted.

### [Etching Apparatus]

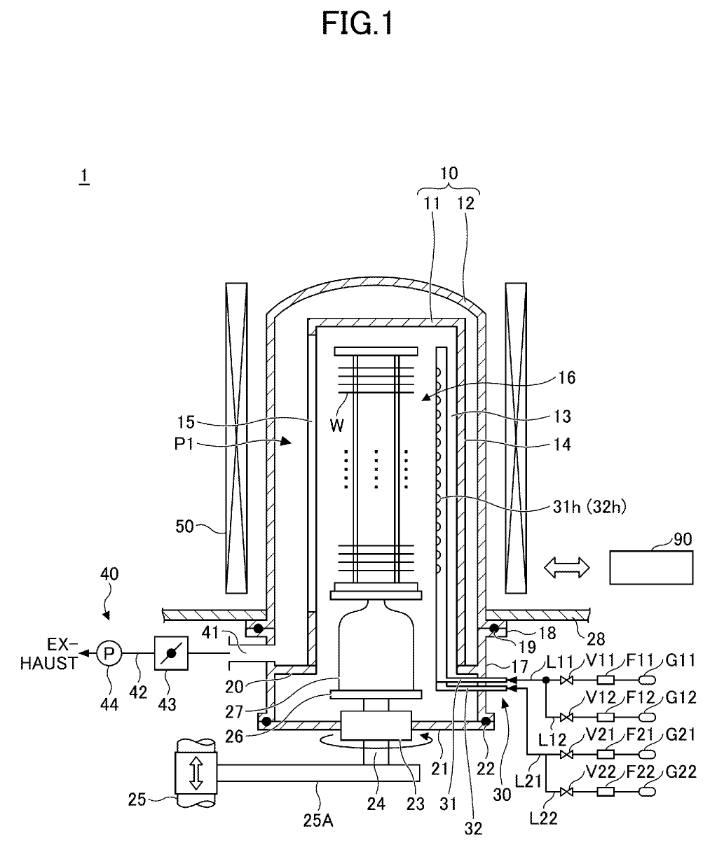

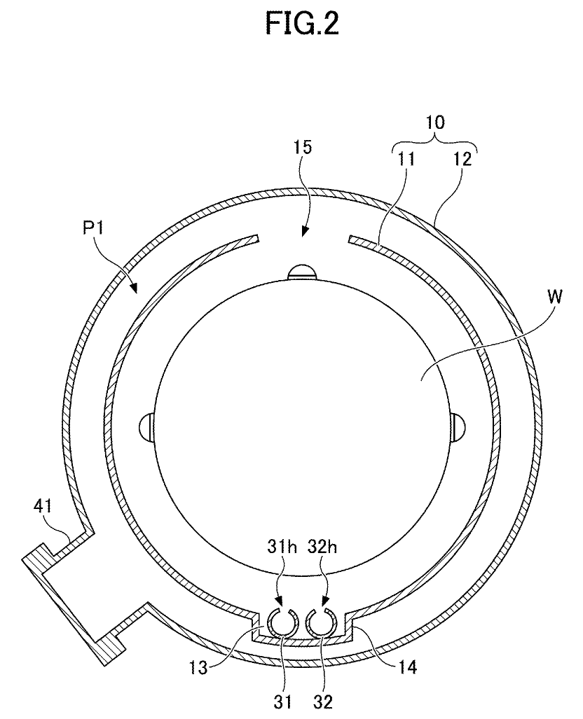

An etching apparatus 1 according to an embodiment of the present disclosure will be described with reference to FIGS. 1 and 2. FIG. 1 is a vertical cross-sectional diagram illustrating the etching apparatus 1 according to the embodiment. FIG. 2 is a horizontal cross-sectional diagram illustrating the etching apparatus 1 according to the embodiment.

The etching apparatus 1 is a batch-type apparatus configured to process a plurality of substrates W at one time. The substrate W is, for example, a semiconductor wafer. The etching apparatus 1 includes a processing chamber 10, a gas supply 30, a gas exhauster 40, a heater 50, and a controller 90.

The internal pressure of the processing chamber 10 can be reduced. The processing chamber 10 is configured to house the substrates W. The processing chamber 10 includes an inner tube 11 and an outer tube 12. The inner tube 11 has a cylindrical shape having a ceiling and an opened bottom end. The outer tube 12 has a cylindrical shape having a ceiling and an opened bottom end, and covers the outside of the inner tube 11. The inner tube 11 and the outer tube 12 are formed of a heat-resistant material, such as quartz or the like. The inner tube 11 and the outer tube 12 have a double-tube structure in which they are arranged coaxially.

The side wall of the inner tube 11 is provided with a housing 13 configured to house a gas supply tube along the longitudinal direction (vertical direction) of the inner tube 11. For example, a part of the side wall of the inner tube 11 is projected outward to form a projecting portion 14, and the interior of the projecting portion 14 is formed as the housing 13.

The side wall of the inner tube 11 is provided with a rectangular opening 15 that is along the longitudinal direction of the inner tube 11. The opening 15 faces the housing 13.

The opening 15 is a gas exhaust opening formed to allow the gas in the inner tube 11 to be exhausted. The length of the opening 15 is the same as the length of a boat 16, or is longer than the length of the boat 16, specifically, the opening 15 is formed to vertically extend beyond both vertical ends of the boat 16.

The bottom end of the processing chamber 10 is supported by a cylindrical manifold 17. The manifold 17 is formed, for example, of stainless steel. A flange 18 is formed at the top end of the manifold 17. The flange 18 supports the bottom end of the outer tube 12. A sealing 19, such as an O-ring or the like, is provided between the flange 18 and the bottom end of the outer tube 12. Thus, the interior of the outer tube 12 is maintained to be airtight.

The inner wall of the upper portion of the manifold 17 is provided with an annular support 20. The support 20 supports the bottom end of the inner tube 11. A cover 21 is airtightly attached to an opening at the bottom end of the manifold 17 via a sealing 22, such as an O-ring or the like. Thus, the opening at the bottom end of the processing chamber 10, i.e., the opening of the manifold 17, is airtightly closed. The cover 21 is formed, for example, of stainless steel.

The center portion of the cover 21 is provided, via a magnetic fluid seal 23, with a rotating shaft 24 that penetrates through the cover 21. The lower portion of the rotating shaft 24 is rotatably supported by an arm 25A of a raising and lowering mechanism 25 that is implemented by a boat elevator.

The top end of the rotating shaft 24 is provided with a rotating plate 26. A boat 16 configured to hold the substrates W is placed over the rotating plate 26 via a temperature-retaining stage 27 formed of quartz. The boat 16 is rotated by rotating the rotating shaft 24. The boat 16 is vertically moved integrally with the cover 21 by raising and lowering the raising and lowering mechanism 25. Thus, the boat 16 is inserted into and removed from the processing chamber 10. The boat 16 can be housed in the processing chamber 10. The boat 16 holds the substrates W (e.g., 50 to 150 substrates) at intervals in a vertically stacked manner. The boat 16 substantially horizontally holds the substrates W at intervals in the vertical direction.

The gas supply 30 is configured to supply various gases into the inner tube 11. The gas supply 30 includes a gas nozzle 31 and a gas nozzle 32. The gas nozzle 31 is an example of a first gas nozzle. The gas nozzle 32 is an example of a second gas nozzle. The gas nozzle 31 and the gas nozzle 32 are formed, for example, of quartz. The gas supply 30 may further include another gas nozzle.

The gas nozzle 31 is fixed to the manifold 17. The gas nozzle 31 vertically extends in a straight line near the inner tube 11, and bends in an L shape in the manifold 17 and horizontally extends to penetrate through the manifold 17. A plurality of gas holes 31h are provided at a portion of the gas nozzle 31 that is positioned in the inner tube 11. The gas holes 31h are formed at predetermined intervals along the vertical direction. The gas holes 31h horizontally discharge a gas toward the substrate W from the outside in the radial direction of the substrate W. The gas holes 31h discharge the gas parallel to the main surface of the substrate W.

A supply path L11 is connected to the gas nozzle 31. The supply path L11 is provided with a supply source G11 of a hydrogen fluoride (HF) gas, a mass flow controller F11, and a valve V11 in order from upstream to downstream in the gas flow direction. The hydrogen fluoride gas is an example of a halogen-containing gas. The supply timing of the hydrogen fluoride gas from the supply source G11 is controlled by the valve V11, and the flow rate of the hydrogen fluoride gas is adjusted to a predetermined rate by the mass flow controller F11. The hydrogen fluoride gas flows into the gas nozzle 31 from the supply path L11, and is discharged into the inner tube 11 from the gas holes 31h.

A supply path L12 is connected to the supply path L11 at a portion downstream of the valve V11. The supply path L12 is provided with a supply source G12 of a nitrogen gas, a mass flow controller F12, and a valve V12 in order from upstream to downstream in the gas flow direction. The nitrogen gas is an example of an inert gas. The supply timing of the nitrogen gas from the supply source G12 is controlled by the valve V12, and the flow rate of the nitrogen gas is adjusted to a predetermined flow rate by the mass flow controller F12. The nitrogen gas flows into the gas nozzle 31 from the supply path L12, and is discharged into the inner tube 11 from the gas holes 31h.

The gas nozzle 32 is fixed to the manifold 17. The gas nozzle 32 vertically extends in a straight line near the inner tube 11, and bends in an L shape in the manifold 17 and horizontally extends to penetrate through the manifold 17. The gas nozzle 32 and the gas nozzle 31 are provided side by side in the circumferential direction of the inner tube 11. A plurality of gas holes 32h are provided at a portion of the gas nozzle 32 that is positioned in the inner tube 11. The gas holes 32h are formed at predetermined intervals along the vertical direction. The gas holes 32h horizontally discharge a gas toward the substrate W from the outside in the radial direction of the substrate W. The gas holes 32h discharge the gas parallel to the main surface of the substrate W.

A supply path L21 is connected to the gas nozzle 32. The supply path L21 is provided with a supply source G21 of an ammonia (NH₃) gas, a mass flow controller F21, and a valve V21 in order from upstream to downstream in the gas flow direction. The ammonia gas is an example of a basic gas. The supply timing of the ammonia gas from the supply source G21 is controlled by the valve V21, and the flow rate of the ammonia gas is adjusted to a predetermined flow rate by the mass flow controller F21. The ammonia gas flows into the gas nozzle 32 from the supply path L21, and is discharged into the inner tube 11 from the gas holes 32h.

A supply path L22 is connected to the supply path L21 at a portion downstream of the valve V21. The supply path L22 is provided with a supply source G22 of a nitrogen gas, a mass flow controller F22, and a valve V22 in order from upstream to downstream in the gas flow direction. The nitrogen gas is an example of an inert gas. The supply timing of the nitrogen gas from the supply source G22 is controlled by the valve V22, and the flow rate of the nitrogen gas is adjusted to a predetermined flow rate by the mass flow controller F22. The nitrogen gas flows into the gas nozzle 32 from the supply path L22, and is discharged into the inner tube 11 from the gas holes 32h.

The gas exhauster 40 is configured to exhaust the gas that is discharged through the opening 15 from the interior of the inner tube 11 and then discharged from a gas outlet 41 through a space P1 between the inner tube 11 and the outer tube 12. The gas outlet 41 is formed at the side wall upward of the manifold 17 and above the support 20. A gas exhaust path 42 is connected to the gas outlet 41. A pressure regulating valve 43 and a vacuum pump 44 are sequentially disposed in the gas exhaust path 42 with a gap such that the internal gas of the processing chamber 10 can be exhausted.

The heater 50 is provided around the outer tube 12. The heater 50 is provided, for example, over a base plate 28. The heater 50 has a cylindrical shape to cover the outer tube 12. The heater 50 includes, for example, a heat generator, and is configured to heat the interior of the processing chamber 10 and the substrates W in the processing chamber 10.

The controller 90 is an electronic circuit or circuitry (including a processor), such as a central processing unit (CPU), a graphics processing unit (GPU), a field programmable gate array (FPGA), an application specific integrated circuit (ASIC), or the like. The controller 90 is configured to execute various controls described in the present specification by executing instruction codes stored in a memory or by being designed as a circuit for specific applications.

### [Etching Method]

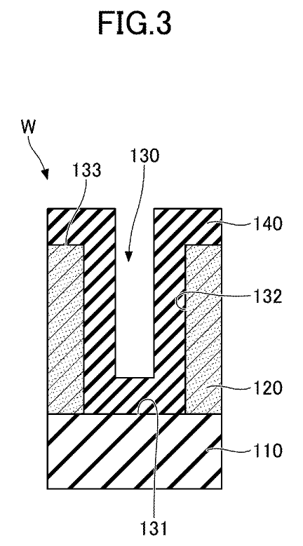

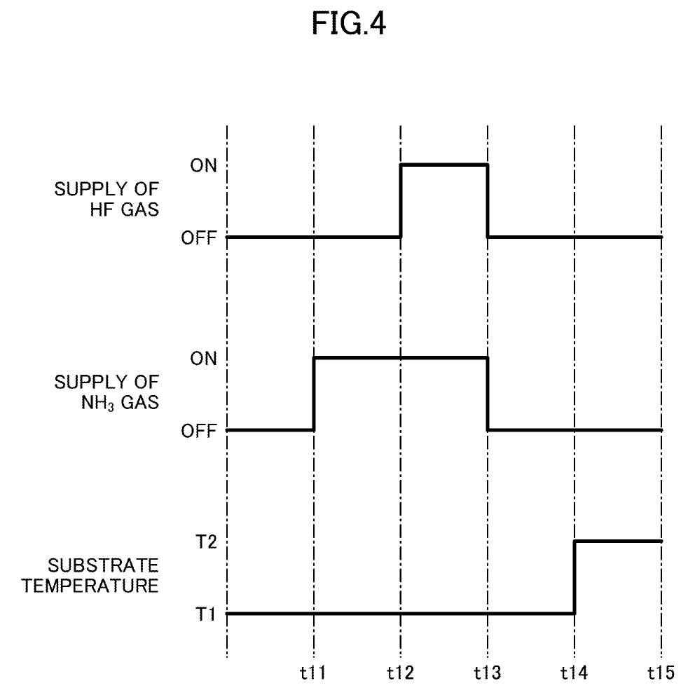

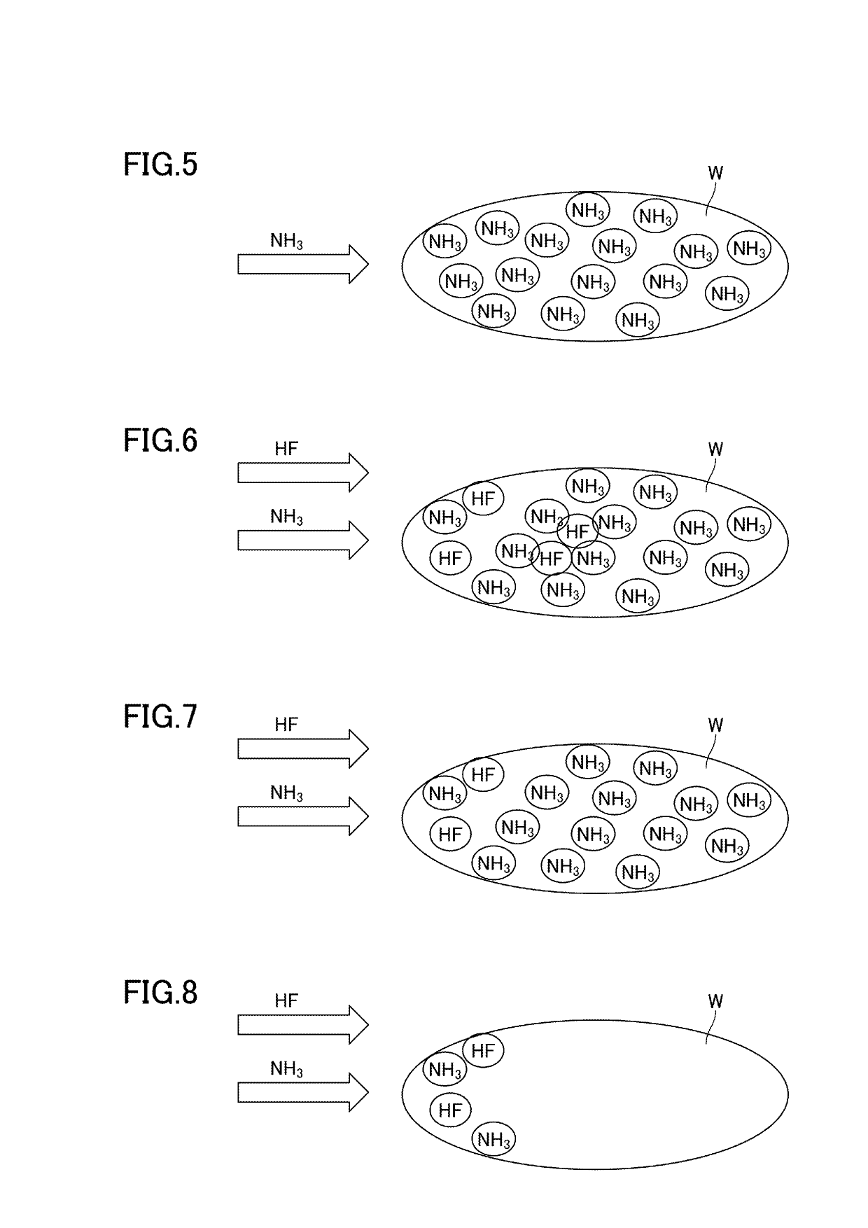

An etching method according to an embodiment of the present disclosure will be described with reference to FIGS. 3 to 8. FIG. 3 is a diagram illustrating an example of the substrate W. FIG. 4 is a timing chart illustrating an etching method according to the embodiment. FIGS. 5 to 8 are diagrams for describing a reaction on the surface of the substrate W. The etching method according to the embodiment is performed under the control of the controller 90.

First, the controller 90 causes the arm 25A to rise to transfer, into the processing chamber 10, the boat 16 holding the plurality of the substrates W, and causes the cover 21 to airtightly close the lower-end opening of the processing chamber 10. As illustrated in FIG. 3, for example, each of the substrates W includes a silicon nitride film 110, a silicon film 120, and a silicon nitride film 140. The silicon nitride film 110 includes a flat top surface. The silicon film 120 is provided over the top surface of the silicon nitride film 110. The silicon film 120 has a projecting shape. The silicon film 120 is, for example, an amorphous silicon film. The silicon nitride film 110 and the silicon film 120 form a recess 130. The recess 130 includes a bottom surface 131, a side surface 132, and a top surface 133. The silicon nitride film 110 forms the bottom surface 131. The silicon film 120 forms the side surface 132 and the top surface 133. Although the silicon nitride film 110 and the silicon film 120 form the recess 130 in the example of FIG. 3 , any type of films can form the recess 130. The silicon nitride film 140 is provided along the inner surface of the recess 130. The silicon nitride film 140 is an example of a first film.

Next, the controller 90 controls the gas exhauster 40 such that the interior of the processing chamber 10 is to be a set pressure and controls the heater 50 such that the interior of the processing chamber 10 is to be a first temperature T1. Thus, the substrates W in the processing chamber 10 are heated to the first temperature T1. The first temperature T1 is, for example, 50 degrees Celsius (°C) or higher and 100°C or lower.

Next, the controller 90 causes the silicon nitride film 140 in the processing chamber 10 to be etched while maintaining the interior of the processing chamber 10 at the first temperature T1. The etching of the silicon nitride film 140 is performed, for example, by a method illustrated in the timing chart of FIG. 4.

At time t11, the controller 90 controls the gas supply 30 to start supply of an ammonia gas from the gas nozzle 32 into the processing chamber 10 without starting supply of a hydrogen fluoride gas from the gas nozzle 31 into the processing chamber 10. The supply of the ammonia gas from the gas nozzle 32 into the processing chamber 10 is continued until time t13.

Since the ammonia gas is supplied without the supply of the hydrogen fluoride gas into the processing chamber 10 during a period from time t11 to time t12, the ammonia gas is distributed throughout the interior of the processing chamber 10. As a result, as illustrated in FIG. 5, the ammonia gas is distributed over the entire surface of each substrate W.

During the period from time t11 to time t12, the controller 90 may control the gas supply 30 to supply a nitrogen gas from the gas nozzle 32 into the processing chamber 10. In this case, since the flow rate of the ammonia gas supplied from the gas nozzle 32 is increased, the period for the ammonia gas to be distributed throughout the interior of the processing chamber 10 is reduced.

At time t12, the controller 90 controls the gas supply 30 to start the supply of the hydrogen fluoride gas from the gas nozzle 31 into the processing chamber 10 while continuing the supply of the ammonia gas from the gas nozzle 32 into the processing chamber 10. The supply of the hydrogen fluoride gas from the gas nozzle 31 into the processing chamber 10 is continued until time t13.

During the period from time t12 to time t13, the hydrogen fluoride gas and the ammonia gas are supplied into the processing chamber 10. Thus, the hydrogen fluoride gas and the ammonia gas react with the silicon nitride film 140 formed over the surface of each substrate W, thereby forming a modified layer. The modified layer contains, for example, ammonium silicofluoride [(NH₄)₂SiF₆].

At the time (time t12) of the start of the combined supply of the hydrogen fluoride gas and the ammonia gas into the processing chamber 10, the ammonia gas is previously spread over the entire surface of each substrate W. Therefore, by controlling the flow rate of the hydrogen fluoride gas and adjusting how the hydrogen fluoride gas flows onto the surface of the substrate W, it is possible to adjust the thickness distribution of the modified layer in the surface of the substrate W. For example, as illustrated in FIG. 6, the hydrogen fluoride gas is supplied under conditions in which substantially equal amounts of the hydrogen fluoride gas reach the center of the substrate W and the end of the substrate W. This can form a modified layer having a thickness distribution in which the thickness of the modified layer at the center of the substrate W is substantially equal to the thickness of the modified layer at the end of the substrate W, or a modified layer having a thickness distribution in which the thickness of the modified layer at the center of the substrate W is larger than the thickness of the modified layer at the end of the substrate W. For example, as illustrated in FIG. 7, the hydrogen fluoride gas is supplied under conditions in which the amount of the hydrogen fluoride gas is larger at the end of the substrate W than at the center of the substrate W. This can form a modified layer having a thickness distribution in which the thickness of the modified layer at the center of the substrate W is smaller than the thickness of the modified layer at the end of the substrate W. When the ammonia gas is not supplied into the processing chamber 10 before the combined supply of the hydrogen fluoride gas and the ammonia gas into the processing chamber 10, the ammonia gas is not distributed over the entire surface of each substrate W at time t12. Therefore, as illustrated in FIG. 8, since a modified layer is formed from the end of the substrate W, it is difficult to adjust the thickness distribution of the modified layer in the surface of the substrate W.

Also, when the ammonia gas is previously distributed over the entire surface of each substrate W at the time (time t12) of the start of the combined supply of the hydrogen fluoride gas and the ammonia gas into the processing chamber 10, it is possible to adjust the thickness distribution of the modified layer in the surface of the substrate W among the plurality of the substrates W.

During the period from time t12 to time t13, the controller 90 may control the gas supply 30 to supply the nitrogen gas from the gas nozzle 31 into the processing chamber 10. In this case, by controlling the flow rate of the nitrogen gas supplied from the gas nozzle 31 into the processing chamber 10, it is possible to adjust the flow rate of the hydrogen fluoride gas supplied from the gas nozzle 31. For example, increasing the flow rate of the nitrogen gas supplied from the gas nozzle 31 into the processing chamber 10 increases the flow rate of the hydrogen fluoride gas supplied from the gas nozzle 31, and thus the hydrogen fluoride gas easily reaches the center of each substrate W. This increases the ratio of the thickness of the modified layer formed at the center of the substrate W to the thickness of the modified layer formed at the end of the substrate W.

During the period from time t12 to time t13, the controller 90 may control the gas supply 30 to supply the nitrogen gas from the gas nozzle 32 into the processing chamber 10. In this case, by controlling the flow rate of the nitrogen gas supplied from the gas nozzle 32 into the processing chamber 10, it is possible to adjust the ammonia gas supplied from the gas nozzle 32. For example, increasing the flow rate of the nitrogen gas supplied from the gas nozzle 32 into the processing chamber 10 increases the flow rate of the ammonia gas supplied from the gas nozzle 32, and thus the ammonia gas easily reaches the center of each substrate W. This increases the ratio of the thickness of the modified layer formed at the center of the substrate W to the thickness of the modified layer formed at the end of the substrate W.

At time t13, the controller 90 controls the gas supply 30 to stop the supply of the hydrogen fluoride gas and the nitrogen gas from the gas nozzle 31 into the processing chamber 10 and to stop the supply of the ammonia gas and the nitrogen gas from the gas nozzle 32 into the processing chamber 10. Thus, during the period from time t13 to time t14, the interior of the processing chamber 10 is evacuated, and the hydrogen fluoride gas and the ammonia gas remaining in the processing chamber 10 are discharged from the processing chamber 10.

At time t14, the controller 90 controls the heater 50 such that the interior of the processing chamber 10 is to be a second temperature T2 that is higher than the first temperature T1. The second temperature is equal to or higher than a temperature at which ammonium silicofluoride is sublimated, e.g., 200°C or higher. Thus, the substrate W is annealed at the second temperature T2, and the ammonium silicofluoride is sublimated. This causes etching of the silicon nitride film 140 formed over the surface of each substrate W. Here, since the thickness distribution of the modified layer in the surface of the substrate W is adjusted, the silicon nitride film 140 is etched in a distribution the same as the adjusted thickness distribution of the modified layer. Thus, by adjusting the thickness distribution of the modified layer, it is possible to adjust the distribution of the etching level in the surface of the substrate W. Also, since the thickness distribution of the modified layer in the surface of the substrate W is uniform among the plurality of the substrates W, the etching shape of the silicon nitride film 140 can be uniform among the plurality of the substrates W.

### [Experimental Results]

In an Example, first, a substrate including a silicon nitride film over the surface of the substrate was provided. Next, the provided substrate was housed in the processing chamber 10 of the etching apparatus 1. Next, the silicon nitride film was etched in the processing chamber 10 by the etching method illustrated in the timing chart of FIG. 4. Specifically, when the silicon nitride film was etched, first, the ammonia gas was supplied to the substrate without supplying the hydrogen fluoride gas, and then the hydrogen fluoride gas and the ammonia gas were supplied to the substrate partway through the etching process. In the Example, the thicknesses of the silicon nitride film before and after the etching were measured, and the difference between the thicknesses of the silicon nitride film before and after the etching was calculated as the etching level of the silicon nitride film.

In a Comparative Example, similar to the Example, a substrate including a silicon nitride film over the surface of the substrate was provided. Next, the provided substrate was housed in the processing chamber 10 of the etching apparatus 1. Next, the hydrogen fluoride gas and the ammonia gas were supplied to the substrate in the processing chamber 10. In the Comparative Example, supply of the ammonia gas without supplying the hydrogen fluoride gas to the substrate was not performed. In the Comparative Example, the thicknesses of the silicon nitride film before and after the etching were measured similar to the Example, and the difference between the thicknesses of the silicon nitride film before and after the etching was calculated as the etching level of the silicon nitride film.

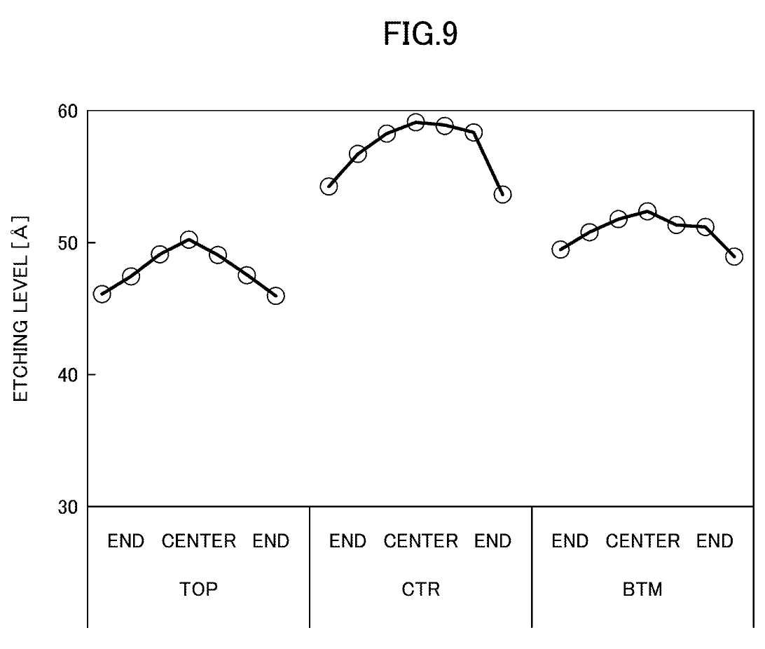

FIG. 9 is a diagram illustrating distributions of etching levels in the surface of the substrate according to the Example. FIG. 9 illustrates the distributions of the etching levels [angstrom] of the silicon nitride film in the surface of the substrate when the substrate is housed at a top (TOP) portion, a central (CTR) portion, or a bottom (BTM) portion of the boat 16. As illustrated in FIG. 9, in the Example, it is found that the etching level of the silicon nitride film tends to be higher at the center than at the end in all the portions of TOP, CTR, and BTM. This result indicates that, according to the Example, it is possible to allow the etching shape of the silicon nitride film to be uniform among a plurality of substrates.

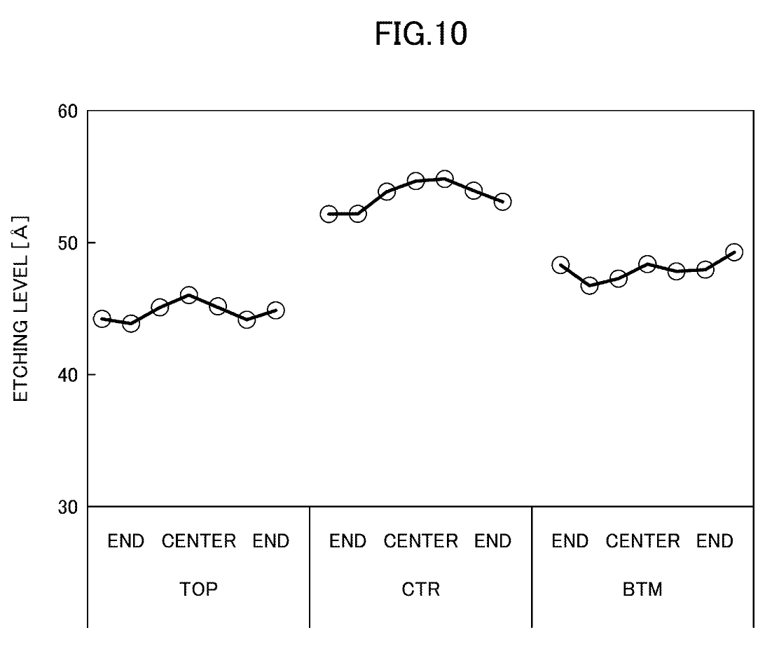

FIG. 10 is a diagram illustrating distributions of etching levels in the surface of the substrate according to the Comparative Example. FIG. 10 illustrates the distributions of the etching levels [angstrom] of the silicon nitride film in the surface of the substrate when the substrate is housed at a top (TOP) portion, a central (CTR) portion, or a bottom (BTM) portion of the boat 16. As illustrated in FIG. 10, it is found that, in the Comparative Example, the distribution of the etching level in the surface of the substrate at the TOP and BTM portions tends to be different from the distribution of the etching level in the surface of the substrate at the CTR portion. This result indicates that, according to the Comparative Example, it is difficult to allow the etching shape of the silicon nitride film to be uniform among a plurality of substrates.

The embodiments disclosed herein should be considered to be exemplary in all respects, not to be restrictive. Omissions, substitutions, and modifications may be made in various forms to the above-described embodiments without departing from the scope and intent of the claims recited.

Although the above embodiments have been described based on the case in which the halogen-containing gas is a hydrogen fluoride gas, the present disclosure is not limited to this. The halogen-containing gas may be a fluorine (F₂) gas, a chlorine trifluoride (ClF₃) gas, or a nitrogen trifluoride (NF₃) gas.

Although the above embodiments have been described based on the case in which the basic gas is an ammonia gas, the present disclosure is not limited to this. The basic gas may be dimethylamine, trimethylamine, or hydrazine.

Although the above embodiments have been described based on the case in which the inert gas is a nitrogen gas, the present disclosure is not limited to this. The inert gas may be a noble gas, such as a helium (He) gas, a neon (Ne) gas, an argon (Ar) gas, or the like.

Although the above embodiments have been described based on the case in which the first film is a silicon nitride film, the present disclosure is not limited to this. The first film may be a silicon oxide film, an SiON film, an SiOCN film, an SiBN film, or an SiOC film.

Although the above embodiments have been described based on the case in which the etching apparatus is a batch-type apparatus configured to process a plurality of substrates at one time, the present disclosure is not limited to this. For example, the etching apparatus may be a single-substrate-type apparatus configured to process substrates one by one.

According to the present disclosure, it is possible to adjust the distribution of the etching level in the surface of the substrate.

What is claimed is:

1. An etching method, comprising:
providing a substrate including a first film over a surface of the substrate; and
etching the first film, wherein
the etching includes:
supplying a first gas toward the substrate from outside in a radial direction of the substrate, the first gas containing a basic gas and not containing a halogen-containing gas; and
after the supply of the first gas, supplying a second gas toward the substrate from the outside in the radial direction of the substrate, the second gas containing both the basic gas and the halogen-containing gas.

2. The etching method according to claim 1, wherein
the etching includes, after the supply of the second gas, annealing the substrate at a temperature that is higher than a temperature at which the second gas is supplied.

3. The etching method according to claim 1, wherein
the first gas and the second gas are supplied, in parallel, to a main surface of the substrate.

4. The etching method according to claim 1, wherein
the halogen-containing gas is supplied from a first gas nozzle to the substrate along with an inert gas.

5. The etching method according to claim 1, wherein
the basic gas is supplied from a second gas nozzle to the substrate along with an inert gas.

6. The etching method according to claim 1, wherein
a recess is formed in the surface of the substrate, and
the first film is formed along an inner surface of the recess.

7. The etching method according to claim 1, wherein
the first film is a silicon nitride film.

8. The etching method according to claim 1, wherein
the halogen-containing gas is a hydrogen fluoride gas, and
the basic gas is an ammonia gas.

9. An etching apparatus, comprising:
a processing chamber configured to house a substrate;
a gas supply configured to supply a gas into the processing chamber; and
a controller, wherein
the controller includes circuitry configured to:
provide a substrate including a first film over a surface of the substrate; and
etch the first film, and wherein
the etching includes:
supplying a first gas toward the substrate from outside in a radial direction of the substrate, the first gas containing a basic gas and not containing a halogen-containing gas; and
after the supply of the first gas, supplying a second gas toward the substrate from the outside in the radial direction of the substrate, the second gas containing both the basic gas and the halogen-containing gas.
